(19) United States
(12) Patent Application Publication
(10) Pub. No.: US 2026/0322504 A1
(43) Pub. Date: Oct. 15, 2026

(54) SEMICONDUCTOR DEVICE AND METHOD OF MANUFACTURING THE SAME

(71) Applicant: SHANGHAI XIZHI TECHNOLOGY CO., LTD., Shanghai (CN)

(72) Inventors: Yichen SHEN, Shanghai (CN); Huaiyu MENG, Shanghai (CN); Yelong XU, Shanghai (CN); Jian ZHU, Shanghai (CN); Shanshan Yu, Shanghai (CN)

(21) Appl. No.: 19/689,375

(22) Filed: May 27, 2026

Related U.S. Application Data
(63) Continuation of application No. PCT/CN2024/133722, filed on Nov. 22, 2024.

(30) Foreign Application Priority Data
Nov. 30, 2023 (CN) 202311628850.1

(51) Int. Cl. H04B 10/80; G02F 1/21; H04B 10/27; H04B 10/40; H04B 10/564; H05K 1/181; H05K 3/303; H10B 80/00; H10D 80/30; H10W 90/10; H10W 90/28

(52) U.S. Cl. CPC H04B 10/801; H04B 10/27; H04B 10/40; H04B 10/564; H05K 1/181; H05K 3/303; G02F 1/212; H05K 2201/10121; H05K 2201/10212; H10B 80/00; H10D 80/30; H10W 90/10; H10W 90/28

(57) ABSTRACT

The present invention provides a semiconductor device implementing interconnection through an on-chip all-optical switching network module, and a method of manufacturing the same. The semiconductor device comprises: a circuit board comprising a plurality of electrical connection paths; an on-chip all-optical switching network module mounted on the circuit board and including a photonic chip and a plurality of analog electrical transceiver chips mounted above the photonic chip, the photonic chip including a plurality of communication nodes respectively communicatively connected to the analog electrical transceiver chips, a plurality of optical connection paths, and at least one on-chip optical switch configured to reconfigure a connection topology among the communication nodes; and a plurality of computing modules mounted on the circuit board and respectively communicatively connected to the analog electrical transceiver chips through the electrical connection paths, such that a connection topology among the computing modules is reconfigurable through the on-chip optical switch.

### CROSS-REFERENCE TO RELATED APPLICATION(S)

This application claims priority to and other related benefits of Chinese Patent Application No. 202311628850.1, filed on Nov. 30, 2023, and entitled “Semiconductor Device and Method of Manufacturing the Same,” the entire content of which is incorporated herein by reference.

### FIELD OF THE INVENTION

The present invention relates to the field of computer technology, and more particularly, to a semiconductor device and a method of manufacturing the same.

### BACKGROUND OF THE INVENTION

According to data released by OpenAI, the growth rate of computational demand for artificial intelligence (AI) models far exceeds the growth rate of computing capability provided by computing hardware. AI accelerators achieve continuous improvements in computing power through semiconductor process iteration and chip architecture innovation, while interconnection bandwidth between AI accelerators also continues to increase. Accordingly, AI accelerator interconnection networks have become critical to improving overall computing performance. The Open Compute Project (OCP) has introduced the OCP Accelerator Module (OAM) having a universal form factor, which has been adopted by leading graphics processing unit (GPU) suppliers. At present, the communication topology among mainstream OCP AI accelerator modules having the universal form factor is typically as follows: as shown in FIG. 1, eight computing modules 100 achieve point-to-point full interconnection through traces 105 on a printed circuit board (PCB) 700. Because PCB traces exhibit relatively high transmission loss, high-speed interfaces generally incur latency and power-consumption penalties. In addition, because relatively long PCB traces are required, the computing modules generally employ interfaces such as CEI long-reach (LR) SerDes interfaces. In the fully connected structure shown in FIG. 1, each SerDes interface communicates with only one specific computing module, thereby further reducing the bandwidth between each pair of computing modules.

Furthermore, because the response characteristics of an electrical channel degrade as signal rate increases, higher-speed interfaces generally involve more complex architectures and circuit designs, thereby introducing additional latency penalties. Such interfaces also consume more power and occupy a larger chip area, thereby limiting chip input/output (IO) bandwidth. Moreover, longer metal interconnect distances further degrade the loss characteristics of the circuit, thereby limiting the interconnection distance between AI accelerators.

### SUMMARY OF THE INVENTION

In view of the deficiencies in the related art described above, the present invention provides a semiconductor device implementing interconnection through an on-chip all-optical switching network module, and a method of manufacturing the same.

According to one embodiment of the present invention, a semiconductor device is provided. The semiconductor device comprises:
a circuit board comprising a plurality of electrical connection paths;
an on-chip all-optical switching network module mounted on the circuit board, the on-chip all-optical switching network module including a photonic chip and a plurality of analog electrical transceiver chips mounted above the photonic chip, wherein the photonic chip comprises a plurality of communication nodes respectively communicatively connected to the plurality of analog electrical transceiver chips, a plurality of optical connection paths, and at least one on-chip optical switch configured to reconfigure a connection topology among the plurality of communication nodes; and
a plurality of computing modules mounted on the circuit board and respectively communicatively connected to the plurality of analog electrical transceiver chips of the on-chip all-optical switching network module through the plurality of electrical connection paths on the circuit board, such that a connection topology among the plurality of computing modules is reconfigurable through the at least one on-chip optical switch.

Compared with electrical interconnection, optical interconnection channels exhibit substantially constant loss across different frequencies and have relatively low loss values, thereby supporting longer transmission distances. The on-chip all-optical switching network module of the present invention combines optical interconnection technology with optical switching technology, thereby enabling more uniform bandwidth distribution within and between nodes and facilitating large-scale expansion of the computing modules.

In some embodiments of the present invention, the circuit board comprises a first socket, and the on-chip all-optical switching network module is removably inserted into the first socket.

In some embodiments of the present invention, the circuit board comprises a plurality of mounting regions, and the plurality of computing modules are respectively mounted in the plurality of mounting regions. The plurality of computing modules are communicatively connected to the first socket through the plurality of electrical connection paths.

In some embodiments of the present invention, the plurality of computing modules comprise a first computing module and a second computing module. A communication path between the first computing module and the second computing module comprises: a first electrical connection path connecting the first computing module to the first socket; a second electrical connection path connecting the first socket to a first analog electrical transceiver chip; a third electrical connection path connecting the first analog electrical transceiver chip to a first communication node; a first optical connection path coupling the first communication node to the at least one on-chip optical switch; a second optical connection path coupling the at least one on-chip optical switch to a second communication node; a fourth electrical connection path connecting the second communication node to a second analog electrical transceiver chip; a fifth electrical connection path connecting the second analog electrical transceiver chip to the first socket; and a sixth electrical connection path connecting the first socket to the second computing module.

In some embodiments of the present invention, the photonic chip comprises at least two photonic integrated circuit sub-chips, and adjacent photonic integrated circuit sub-chips are optically interconnected with one another. Each photonic integrated circuit sub-chip includes at least two communication nodes, a plurality of the optical connection paths, and at least one on-chip optical switch. Communication between any two communication nodes on the photonic chip is achieved through the at least one on-chip optical switch and the plurality of optical connection paths.

In some embodiments of the present invention, the on-chip all-optical switching network module further includes at least one optical-switching control analog electrical chip mounted above a corresponding on-chip optical switch and is configured to control the corresponding on-chip optical switch. Each on-chip optical switch and the corresponding optical-switching control analog electrical chip together form an on-chip optical switching module. Accordingly, the on-chip all-optical switching network module includes a plurality of on-chip optical switching modules.

In some embodiments of the present invention, each communication node includes: an electrical-to-optical conversion unit configured to convert information carried by an electrical signal into an optical signal for transmission; and an optical-to-electrical conversion unit configured to convert a received optical signal into an electrical signal carrying received information.

In some embodiments of the present invention, the plurality of analog electrical transceiver chips are mounted on the photonic chip and respectively correspond to the plurality of communication nodes, and are configured such that communication between any two analog electrical transceiver chips is achieved through corresponding communication nodes and at least one on-chip optical switch in the photonic chip.

In some embodiments of the present invention, the electrical-to-optical conversion unit comprises a modulator or a modulator array; and/or the optical-to-electrical conversion unit comprises a detector or a detector array.

In some embodiments of the present invention, the modulator comprises a microring modulator, a Mach-Zehnder modulator, or an electro-absorption modulator; and/or the detector comprises a microring detector or a photodiode.

In some embodiments of the present invention, each photonic integrated circuit sub-chip further includes an optical input coupler and an optical power splitter, wherein the optical input coupler of one photonic integrated circuit sub-chip is configured to couple light from an off-chip light source into the photonic chip, and the optical power splitter is optically connected to the optical input coupler and configured to split the light from the optical input coupler into a plurality of optical outputs. Each optical outputs has substantially the same optical power and is respectively transmitted to a corresponding modulator.

In some embodiments of the present invention, the plurality of optical connection paths include first-type optical waveguides, and adjacent photonic integrated circuit sub-chips are optically interconnected through the first-type optical waveguides.

In some embodiments of the present invention, the first-type optical waveguides of adjacent photonic integrated circuit sub-chips that face each other at a junction therebetween are configured such that a cross-section area of each first-type optical waveguide gradually increases from one photonic integrated circuit sub-chip toward the other photonic integrated circuit sub-chip.

In some embodiments of the present invention, the plurality of optical connection paths further include second-type optical waveguides. In each photonic integrated circuit sub-chip, the second-type optical waveguides are disposed in a different layer from the first-type optical waveguides. One or more of the at least one on-chip optical switch, the electrical-to-optical conversion unit, the optical-to-electrical conversion unit, the optical input coupler, and the optical power splitter are optically connected to corresponding first-type optical waveguides through corresponding second-type optical waveguides. The second-type optical waveguides are optically connected to the first-type optical waveguides through evanescent-wave couplers.

In some embodiments of the present invention, the at least one on-chip optical switch comprises a silicon photonic switch including a plurality of optical switching units. The at least one optical-switching control analog electrical chip is configured to control the plurality of optical switching units to schedule and switch data transmitted through the silicon photonic switch, such that the connection topology among the plurality of communication nodes is reconfigurable.

In some embodiments of the present invention, each optical switching unit comprises a Mach-Zehnder interferometer structure.

In some embodiments of the present invention, each photonic integrated circuit sub-chip is fabricated using a full-reticle photomask exposure process.

In some embodiments of the present invention, each computing module includes a digital chip and a memory, and the digital chip and the memory are integrally packaged on a package substrate.

According to another embodiment of the present invention, a method of manufacturing the semiconductor device described above is provided. The method comprises:
providing a circuit board having a plurality of electrical connection paths;
providing an on-chip all-optical switching network module comprising a photonic chip and a plurality of analog electrical transceiver chips mounted above the photonic chip, wherein the photonic chip includes a plurality of communication nodes respectively communicatively connected to the plurality of analog electrical transceiver chips, a plurality of optical connection paths, and at least one on-chip optical switch configured to reconfigure a connection topology among the plurality of communication nodes;
providing a plurality of computing modules; and
mounting the on-chip all-optical switching network module and the plurality of computing modules on the circuit board, wherein the plurality of computing modules are respectively communicatively connected to the plurality of analog electrical transceiver chips through the plurality of electrical connection paths on the circuit board, such that a connection topology among the plurality of computing modules is reconfigurable through the at least one on-chip optical switch.

In some embodiments of the present invention, the circuit board comprises a first socket, and mounting the on-chip all-optical switching network module on the circuit board comprises removably inserting the on-chip all-optical switching network module into the first socket.

In some embodiments of the present invention, the photonic chip comprises at least two photonic integrated circuit sub-chips, adjacent photonic integrated circuit sub-chips are optically interconnected with one another, and each photonic integrated circuit sub-chip is fabricated using a full-reticle photomask exposure process.

By applying the present invention, various beneficial effects may be achieved.

In the on-chip all-optical switching network module of the present invention, the connection topology among the communication nodes (and corresponding analog electrical transceiver chips) is reconfigurable through the on-chip optical switch, such that interconnection among the computing modules, including digital chips, is no longer fixed but instead becomes field reconfigurable. This configuration enables the topology among the computing modules to be dynamically adjusted according to specific artificial intelligence models. In terms of topology, data-flow requirements of different artificial intelligence models can generally be classified into three categories: data parallelism, in which each chip loads an entire model while different chips process different portions of a dataset; model parallelism, in which particularly large layers of the model are divided among multiple chips for computation; and pipeline parallelism, in which different layers of the model are processed by different chips. Different data flows correspond to different interconnection topologies. By using the reconfigurable optical interconnection architecture of the present invention, different interconnection topologies among chips can be rapidly switched, thereby improving bandwidth utilization and scalability of artificial intelligence computing systems and enabling multiple computing modules to cooperatively accelerate large-scale models efficiently and reliably. In addition, the on-chip all-optical switching network module consumes only several hundred milliwatts of power, which is several orders of magnitude lower than the power consumption of electrical switches, while the reconfiguration latency can generally reach microsecond or even nanosecond levels, thereby enabling real-time optical-path reconfiguration during artificial intelligence model training.

In the semiconductor device of the present invention, the photonic chip of the on-chip all-optical switching network module is formed by interconnecting photonic integrated circuit sub-chips fabricated through full-reticle stitching. Except for a silicon nitride exposure mask corresponding to optical couplers connected to input lasers and communication nodes, exposure masks for other components on the photonic integrated circuit sub-chips are substantially identical, thereby reducing fabrication cost. In addition, the on-chip all-optical switching network architecture reuses the plurality of analog electrical transceiver chips, thereby improving system energy efficiency, overcoming reticle-size limitations, and increasing overall system computational throughput.

Furthermore, commercial implementation of silicon photonic switches typically involves issues associated with optical-fiber coupling and polarization dependence. The present invention employs directly integrated on-chip optical switches, thereby avoiding such issues. Conventional optical switches generally use optical fibers as input/output interfaces, and spacing between arrayed optical fibers is typically about 250 μm or 127 μm. For optical switches having dozens of optical input/output ports, such arrangements not only occupy a large chip area but also reduce coupling yield between optical fibers and chips, thereby aggravating optical coupling loss. The present invention overcomes optical coupling loss issues by employing directly integrated on-chip optical switches. In addition, because conventional submicron silicon-on-insulator waveguides exhibit strong birefringence characteristics, effective refractive indices of transverse-electric and transverse-magnetic polarizations differ significantly, causing couplers and phase shifters based thereon to exhibit polarization dependence. For optical switches using optical-fiber input/output interfaces, reducing polarization dependence has long been a challenge in silicon photonic switch design. In contrast, the present invention employs directly integrated on-chip optical switches having fixed and single waveguide input/output polarization states, thereby effectively avoiding polarization-dependence issues associated with silicon photonic switches while improving waveguide input/output stability. Moreover, the on-chip optical switches are compatible with silicon photonic fabrication processes of the photonic chip, thereby simplifying process flow and reducing manufacturing costs.

In addition, because the on-chip all-optical switching network module is mounted on or removably inserted into the circuit board, the module may also be referred to as a board-mounted on-chip all-optical switching network module. The on-chip all-optical switching network module or the on-chip optical switch does not need to be packaged together with the computing modules or digital chips. Instead, the respective components may be separately mounted on the circuit board, thereby providing flexibility, scalability, and enhanced controllability.

Various aspects, features, and advantages of the present invention will be described in further detail below with reference to the accompanying drawings. From the following detailed description taken in conjunction with the accompanying drawings, the foregoing and other aspects, features, and advantages of the present invention will become more apparent.

### BRIEF DESCRIPTION OF THE DRAWINGS

FIG. 1 is a schematic diagram illustrating point-to-point full interconnection among eight computing modules through circuit board traces in a conventional semiconductor device.

FIG. 2 is a schematic plan view illustrating a semiconductor device according to an embodiment of the present invention.

FIGS. 3A-3C are schematic diagrams illustrating variations in connection topologies among eight computing modules in the semiconductor device shown in FIG. 2.

FIG. 4 is a schematic plan view illustrating an on-chip all-optical switching network module in the semiconductor device shown in FIG. 2.

FIG. 5 is a schematic diagram illustrating a package structure of the semiconductor device shown in FIG. 2.

FIG. 6 is a schematic diagram illustrating a structure of an on-chip optical switch including a plurality of optical switching units.

FIG. 7 is a schematic diagram illustrating a structure of the optical switching unit shown in FIG. 6.

FIG. 8 is a schematic diagram illustrating a stitching coupler for optical-waveguide interconnection between adjacent photonic integrated circuit sub-chips in the on-chip all-optical switching network module shown in FIG. 4.

FIG. 9 is a schematic diagram illustrating an evanescent-wave coupler for optical-waveguide interconnection between different layers of a photonic integrated circuit sub-chip in the on-chip all-optical switching network module shown in FIG. 4.

### DETAILED DESCRIPTION OF THE INVENTION

Exemplary embodiments will be described in greater detail below with reference to the accompanying drawings. Certain terminology may be used in the following description for the purpose of reference only, and thus is not intended to be limiting. For example, terms such as “top”, “bottom”, “upper”, “lower”, “above”, and “below” may be used to refer to directions in the drawings to which reference is made. Terms such as “front”, “back”, “rear”, “side”, “outboard”, and “inboard” may be used to describe the orientation and/or location of portions of the component within a consistent but arbitrary frame of reference which is made clear by reference to the text and the associated drawings describing the component under discussion. Similarly, the terms “first”, “second”, and other such numerical terms referring to structures do not imply any sequence or order unless clearly indicated by the context.

It will be understood that when an element or feature is referred to as being “on,” “connected to,” or “coupled to” another element or layer, it can be directly on, connected to, or coupled to the other element or feature, or one or more intervening elements or features may be present. In addition, it will also be understood that when an element or features is referred to as being “between” two elements or features, it can be the only element or feature between the two elements or features, or one or more intervening elements or features may also be present.

The terminology used herein is for the purpose of describing particular embodiments and is not intended to be limiting of the present invention. Such terminology may include words specifically mentioned herein, their derivatives, and words of similar meaning. As used herein, the singular forms “a” and “an” are intended to include the plural forms as well, unless the context clearly indicates otherwise. It will be further understood that the terms “comprises,” “comprising,” “includes,” and “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. As used herein, the terms “use,” “using,” and “used” may be considered synonymous with the terms “utilize,” “utilizing,” and “utilized,” respectively.

FIG. 2 illustrates an exemplary embodiment of a semiconductor device according to the present invention. As shown in FIG. 2, the semiconductor device comprises a circuit board 500, an on-chip all-optical switching network module 600, and a plurality of computing modules 100. The circuit board 500, for example, a printed circuit board (PCB), is provided with a plurality of electrical connection paths 106. The on-chip all-optical switching network module 600 and the plurality of computing modules 100 are mounted on the circuit board 500. In the present exemplary embodiment, eight computing modules 100 and one on-chip all-optical switching network module 600 are mounted on the circuit board 500. Each computing module 100 is electrically and communicatively connected to the on-chip all-optical switching network module 600 through the electrical connection paths 106. The electrical connection paths 106 include conductive traces on the circuit board 500.

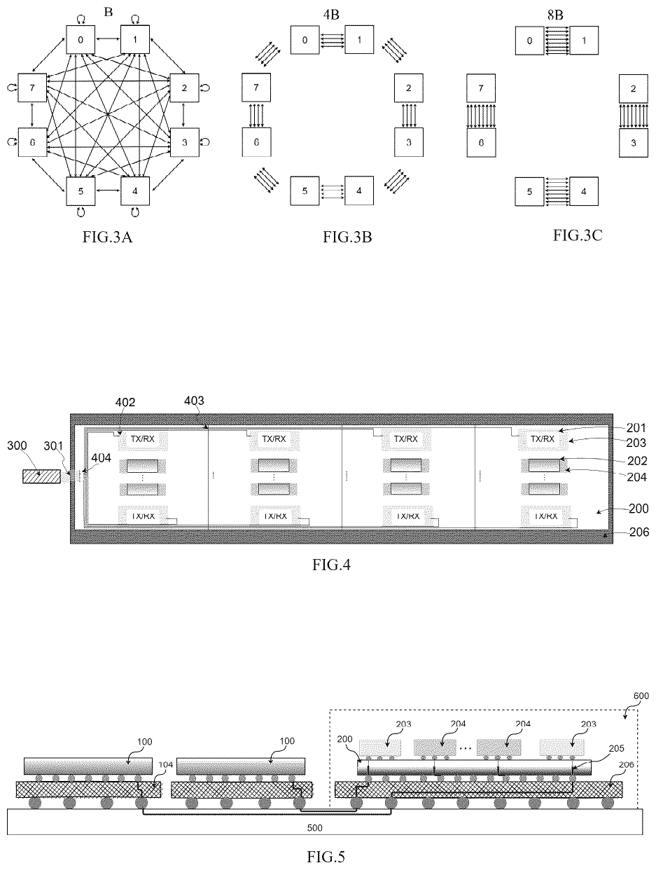

Referring also to FIG. 4, the on-chip all-optical switching network module 600 comprises a photonic chip 200 and a plurality of analog electrical transceiver chips 203 mounted above the photonic chip. The photonic chip includes a plurality of communication nodes (TX/RX) 201, a plurality of optical connection paths, and at least one on-chip optical switch 202. The at least one on-chip optical switch is configured to reconfigure a connection topology among the plurality of communication nodes. The plurality of computing modules 100 are respectively communicatively connected to the plurality of analog electrical transceiver chips 203 of the on-chip all-optical switching network module 600 through the electrical connection paths on the circuit board 500. For example, the computing modules 100 mounted on the circuit board are electrically connected to the analog electrical transceiver chips mounted above the photonic chip through electrical traces on the circuit board via long-reach SerDes interfaces, such that the connection topology among the plurality of computing modules 100 is reconfigurable by the on-chip optical switch. FIGS. 3A-3C schematically illustrate several selectable connection topologies among the eight computing modules 100 shown in FIG. 2. Through the on-chip all-optical switching network module 600, the connection topology among the eight computing modules 100 can be reconfigured. The on-chip optical switch generally changes transmission paths of optical signals based on thermo-optic and electro-optic principles, and the reconfiguration latency is generally on the order of microseconds or even nanoseconds. Accordingly, the on-chip optical network can change input and output connection paths in real time. By controlling the optical switching network, the connection topology among the computing modules 100 can be dynamically configured as a fully connected topology (FIG. 3A), a ring topology (FIG. 3B), a point-to-point topology (FIG. 3C), or any other selectable topology. As shown in FIGS. 3A-3C, the eight computing modules 100 are respectively numbered from 0 to 7. The communication bandwidth between computing module 0 and computing module 1 can be dynamically switched among bandwidth B (fully connected), bandwidth 4B (ring), bandwidth 8B (point-to-point), or other selectable configurations, thereby matching bandwidth requirements of different communication algorithms and improving bandwidth utilization, which in turn improves overall operating efficiency of an artificial-intelligence computing system.

In some embodiments of the present invention, the computing module 100 comprises a digital electrical chip 101 and a memory 102, wherein the digital electrical chip 101 and a series of high bandwidth memories (HBMs) are packaged on a silicon interposer 103, such that the computing module 100 is integrally packaged on a package substrate 104. The circuit board 500 comprises a plurality of mounting regions, and the plurality of computing modules 100 are respectively mounted in the plurality of mounting regions.

In some embodiments of the present invention, the circuit board 500 comprises a first socket, and the on-chip all-optical switching network module 600 is removably inserted into the first socket. The plurality of computing modules 100 are communicatively connected to the first socket through the plurality of electrical connection paths. Accordingly, high-speed electrical signals from the digital electrical chip 101 are transmitted to the edge of the on-chip all-optical switching network module 600 through the traces of the package substrate 104 and the traces 106 of the circuit board 500, signal amplification and electrical-to-optical/optical-to-electrical conversion are performed by components in the on-chip optical network module 600, and then the optical network is reconfigured by the on-chip optical switch to change the interconnection topology among the computing modules 100 or their digital electrical chips 101.

In some embodiments of the present invention, the plurality of computing modules 100 comprise a first computing module and a second computing module. A communication path between the first computing module and the second computing module comprises: a first electrical connection path connecting the first computing module to the first socket; a second electrical connection path connecting the first socket to a first analog electrical transceiver chip; a third electrical connection path connecting the first analog electrical transceiver chip to a first communication node; a first optical connection path connecting the first communication node to the on-chip optical switch; a second optical connection path connecting the on-chip optical switch to a second communication node; a fourth electrical connection path connecting the second communication node to a second analog electrical transceiver chip; a fifth electrical connection path connecting the second analog electrical transceiver chip to the first socket; and a sixth electrical connection path connecting the first socket to the second computing module. In some embodiments of the present invention, the electrical connection paths include metal traces, conductive vias, and the like, and the optical connection paths include optical waveguides, and the like.

In an exemplary embodiment, as shown in FIG. 4, the on-chip all-optical switching network module comprises the photonic chip 200, the plurality of analog electrical transceiver chips 203, and a plurality of optical-switching control analog electrical chips 204. The photonic chip 200 comprises a plurality of on-chip optical switches 202, and each on-chip optical switch 202 and a corresponding optical-switching control analog electrical chip 204 are arranged in a one-to-one correspondence to form an on-chip optical switch module. The on-chip all-optical switching network module comprises a plurality of such on-chip optical switch modules. In some embodiments of the present invention, one photonic chip 200 is packaged on a package substrate 206, and the photonic chip 200 is formed by at least two photonic integrated circuit sub-chips through waveguide stitching, such that adjacent photonic integrated circuit sub-chips are optically interconnected with one another. FIG. 4 shows one photonic chip 200 formed by four photonic integrated circuit sub-chips. Each photonic integrated circuit sub-chip is of full-reticle size, meaning that each photonic integrated circuit sub-chip is fabricated using a full-reticle photomask exposure process. In some embodiments, the photonic chip comprises more than four photonic integrated circuit sub-chips.

Each photonic integrated circuit sub-chip comprises at least two communication nodes (TX/RX) 201 and a plurality of optical connection paths. The plurality of optical connection paths include optical waveguides. For clarity of illustration, routing of silicon nitride waveguide connecting the input and output ports is omitted from FIG. 4. Communication between any two communication nodes 201 is achieved through at least one on-chip optical switch 202 and the plurality of optical connection paths. Above each photonic integrated circuit sub-chip, two identical analog electrical transceiver chips 203 and at least one optical-switching control analog electrical chip 204 are integrated. The analog electrical transceiver chips 203 are mounted above the photonic integrated circuit sub-chip corresponding to the communication nodes 201, the at least one on-chip optical switch 202 is formed as optical elements in the photonic integrated circuit sub-chip, and the optical-switching control analog electrical chips 204 are mounted above the photonic integrated circuit sub-chip in one-to-one correspondence with the on-chip optical switches. Communication between any two analog electrical transceiver chips 203 can be achieved through the corresponding communication nodes and at least one on-chip optical switch in the photonic chip.

In some embodiments of the present invention, each communication node comprises an electrical-to-optical conversion unit and an optical-to-electrical conversion unit. The electrical-to-optical conversion unit is configured to convert information to be transmitted and carried by an electrical signal into an optical signal. For example, the electrical-to-optical conversion unit comprises a modulator or a modulator array. The optical-to-electrical conversion unit is configured to convert a received optical signal into an electrical signal carrying the received information. For example, the optical-to-electrical conversion unit comprises a detector or a detector array. In some embodiments of the present invention, the modulator comprises a microring modulator, a Mach-Zehnder modulator, or an electro-absorption modulator. The detector comprises a microring detector or a photodiode.

In some embodiments of the present invention, each photonic integrated circuit sub-chip further comprises an optical input coupler and an optical power splitter. In the photonic chip 200, the optical input coupler of one of the photonic integrated circuit sub-chips is configured to couple light from an off-chip light source into the photonic chip. The optical power splitter is optically connected to the optical input coupler and is configured to split the light received from the optical input coupler into a plurality of optical outputs, wherein each of the plurality of optical outputs has substantially the same power. The plurality of optical outputs are respectively transmitted to corresponding modulators.

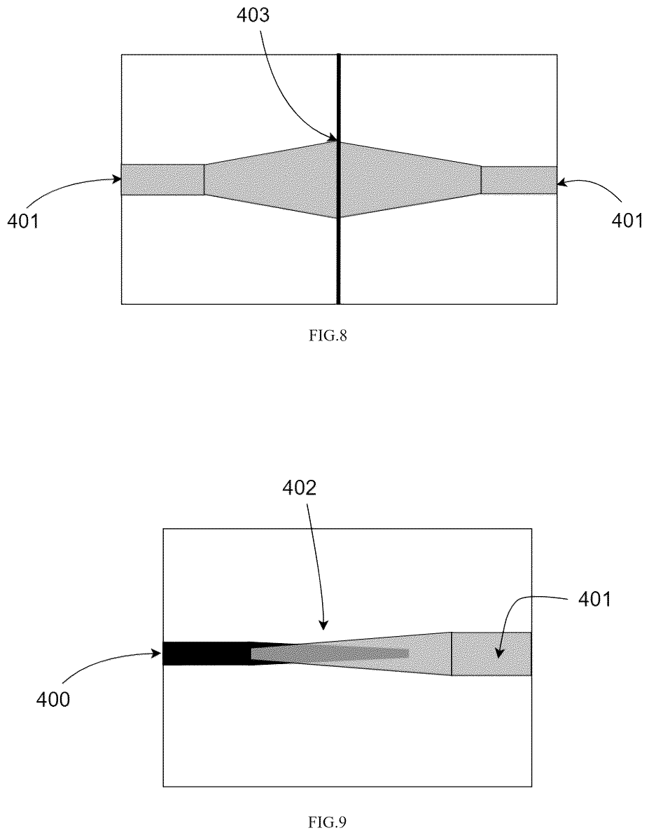

In some embodiments of the present invention, in the photonic chip 200, the plurality of optical connection paths comprise first-type optical waveguides, for example, silicon nitride waveguides, wherein the first-type optical waveguides of two adjacent photonic integrated circuit sub-chips are optically interconnected. In some embodiments of the present invention, as shown in FIG. 8, the first-type optical waveguides 401 of two adjacent photonic integrated circuit sub-chips that face each other at a junction 403 therebetween are configured to have a structure (for example, a horn-like tapered shape) in which a cross-sectional area of the first-type optical waveguides gradually increases from one photonic integrated circuit sub-chip toward the other photonic integrated circuit sub-chip, such that the coupling surface area is increased, the alignment tolerance of the adjacent first-type optical waveguides 401 at the junction of the photonic integrated circuit sub-chips is increased, and the coupling efficiency is improved. In some embodiments of the present invention, the plurality of optical connection paths further comprise second-type optical waveguides, for example, silicon waveguides. In each of the photonic integrated circuit sub-chips, the second-type optical waveguides are disposed in a different layer from the first-type optical waveguides. In each of the photonic integrated circuit sub-chips, one or more of the on-chip optical switch, the electrical-to-optical conversion unit, the optical-to-electrical conversion unit, the optical input coupler, and the optical power splitter are optically connected to corresponding first-type optical waveguides through corresponding second-type optical waveguides. As shown in FIG. 9, the second-type optical waveguides 400 and the first-type optical waveguides 401 are optically connected through an evanescent wave coupler 402.

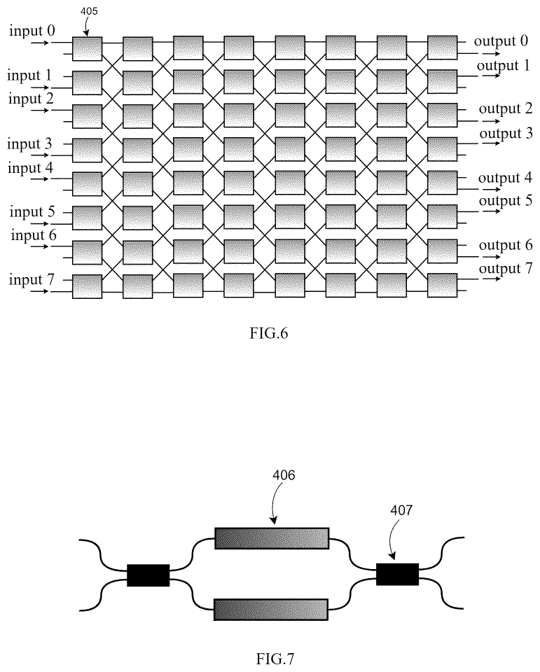

In some embodiments of the present invention, the on-chip optical switch 202 may comprise a silicon photonic switch. As shown in FIG. 6, the silicon photonic switch may comprise a plurality of optical switching units 405. The optical-switching control analog electrical chip 204 is configured to control the plurality of optical switching units 405 to route and switch data transmitted through the switch such that the connection topology among the plurality of communication nodes 201 is reconfigurable. FIG. 6 illustrates an exemplary structure of an 8×8 strictly non-blocking optical switch. The optical switch comprises 64 optical switching units 405. By controlling the signal output port of each switching unit, any path combination between the 8 input channels (input ports 0-7) and the eight output channels (output ports 0-7) in the figure can be realized, and insertion loss on each path is independent of the selected path. For example, input port 0 can be selectively connected to any one of output ports 0 to 7, thereby achieving reconfiguring the optical path and configuring the connection topology in real time. In a specific application, the 8×8 silicon photonic switch may be further replicated laterally, and two or more optical switches may be provided on the same photonic integrated circuit sub-chip to meet larger bandwidth switching requirements. Moreover, because the on-chip all-optical switching network module of the present invention is connected to the circuit board in a pluggable manner, the bandwidth of the semiconductor device can be expanded conveniently and rapidly as needed.

In some embodiments of the present invention, the optical switching unit 405 has a Mach-Zehnder interferometer structure. As shown in FIG. 7, the optical switching unit comprises electro-optic or thermo-optic phase shifters 406 and 2×2 beam splitters 407. By controlling the electro-optic or thermo-optic phase shifters 406 on the upper and lower arms, the phases of the optical signals in the two arms can be changed, such that the output port position can be altered through interference between the optical signals in the two arms, thereby enabling real-time optical-path reconfiguration and dynamic connection-topology configuration. Furthermore, the connection topology among the respective computing modules in the semiconductor device shown in FIG. 2 can be changed from the full interconnection topology shown in FIG. 3A to the ring topology shown in FIG. 3B, the point-to-point topology shown in FIG. 3C, or any other feasible interconnection topology.

Returning to FIG. 5, it illustrates a packaging structure of the semiconductor device shown in FIG. 2. On the circuit board 500, the on-chip all-optical switching network module 600 is connected to a series of computing modules 100. High-speed long-reach SerDes signals from each computing module 100 are transmitted to corresponding analog electrical transceiver chip 203 through metal traces on the package substrate 104, the circuit board 500, and the package substrate 206, and through the through-silicon vias 205. The modulator or modulator array included in the communication node 201 corresponding to the analog electrical transceiver chip 203 on the photonic chip 200 may comprise a microring modulator, a Mach-Zehnder modulator, or an electro-absorption modulator. The detector or detector array is selectively configured with or without a wavelength division demultiplexing device depending on whether the input laser is a multi-wavelength laser or a single-wavelength laser.

Referring to FIG. 4, an off-chip single-wavelength or multi-wavelength laser module 300 generates optical signals that are transmitted through an optical fiber array 301 to an optical input coupler 405, such as an on-chip grating coupler or a facet coupler. The optical input coupler 405 couples the single-wavelength or multi-wavelength laser light into the photonic chip 200. Within the photonic chip 200, a plurality of optical power splitters, such as broadband beam splitters, distribute the optical power substantially evenly to input ports of modulators or modulator arrays located under different analog electrical transceiver chips 203. The modulators or modulator arrays modulate the optical carrier with electrical signals from the corresponding analog electrical transceiver chips 203, thereby loading electrical information onto the optical signals. The modulated optical signals are routed through the on-chip optical switch 202 under control of the optical-switching control analog electrical chip 204 for data scheduling and switching. The routed optical signals are then transmitted via optical waveguides to detectors or detector arrays located under other analog electrical transceiver chips 203, where the modulated optical signals are received and converted into analog electrical signals. The resulting analog electrical signals are transmitted through the circuit board 500 to corresponding computing modules 100 at the receiving side, thereby completing information transmission among different computing modules 100.

Specifically, in an exemplary embodiment, with reference to FIGS. 2, 4, and 5, a low-speed parallel signal (i.e., digital information) from a digital electrical chip 101 at a transmitting side is converted into a high-speed serial signal via a long-reach SerDes interface. The high-speed serial signal is transmitted through metal traces on the package substrate 104, the circuit board 500, and the package substrate 206, as well as through the through-silicon vias 205, to a corresponding analog electrical transceiver chip 203 on the photonic chip 200. The analog electrical transceiver chip 203 generates an electrical signal for optical modulation based on the received high-speed serial signal. A modulator or modulator array located at a communication node 201 corresponding to the transmitting-side analog electrical transceiver chip 203 modulates optical signals input from the laser module 300 based on the electrical signal from the analog electrical transceiver chip, thereby generating a modulated optical signal. In this manner, information carried by the electrical signal is loaded onto the modulated optical signal. The modulated optical signal generated by the modulator or modulator array is transmitted via an optical waveguide to an input port of a corresponding on-chip optical switch 202. The on-chip optical switch 202 determines an output port and reconfigures an optical path under control of an optical-switching control analog electrical chip 204. The modulated optical signal is output from the determined output port of the on-chip optical switch 202 and transmitted via an optically coupled optical waveguide to a detector or detector array located under a receiving-side analog electrical transceiver chip 203. The detector or detector array converts the received modulated optical signal into an analog electrical signal through optical-to-electrical conversion and outputs the analog electrical signal to the corresponding receiving-side analog electrical transceiver chip 203. The receiving-side analog electrical transceiver chip 203 processes the received analog electrical signal and transmits it through the through-silicon vias 205 of the photonic chip 200, as well as through metal traces on the package substrate 206, the circuit board 500, and the package substrate 104, to a long-reach SerDes interface of a corresponding receiving-side digital electrical chip 101. The long-reach SerDes interface converts the received serial signal into a parallel signal, thereby enabling communication between the transmitting-side digital electrical chip 101 and the receiving-side digital electrical chip 101.

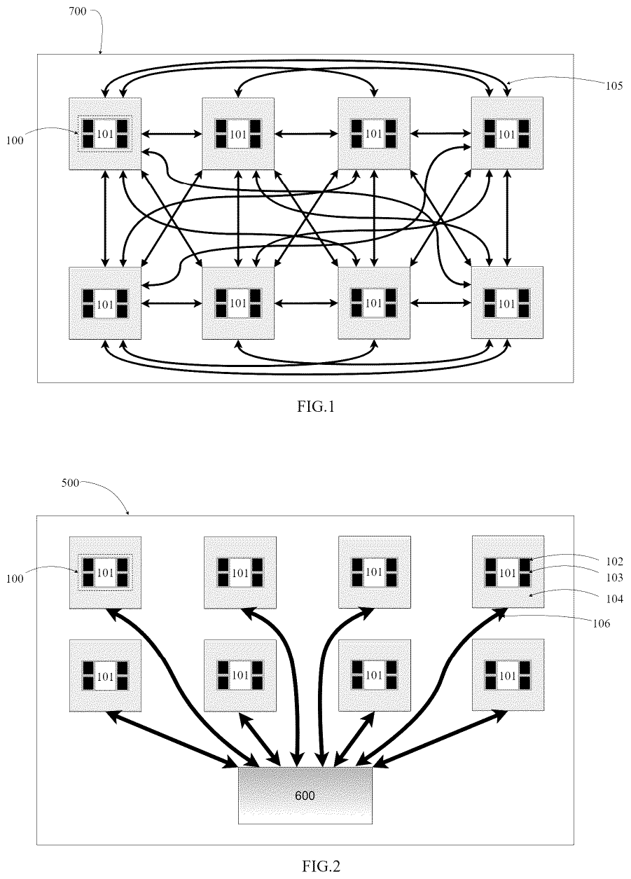

Compared with conventional electrical interconnection structures in the related prior art, signal transmission in the present invention does not pass through any electrical switch, such that high-speed electrical signals from one computing module can reach another computing module with minimum latency. In the conventional semiconductor device shown in FIG. 1, computing modules 100 including digital electrical chips 101 are interconnected with other computing modules 100 on a circuit board 700 in a point-to-point manner via traces 105. Due to the relatively long length of the circuit board traces 105, high-speed interface design is typically complex, and the circuit board 700 requires specialized design to satisfy sufficient link budget requirements. As a result, high-speed interfaces generally incur latency and power consumption penalties.

In contrast, the present invention employs a photonic chip formed by stitching together a plurality of photonic integrated circuit sub-chips of full-reticle size via optical waveguides to serve as an interposer layer. A plurality of analog electrical transceiver chips and optical-switching control analog electrical chips are integrated with the interposer layer to form an on-chip all-optical switching network module. A plurality of computing modules are connected to the on-chip all-optical switching network module via long-reach SerDes interfaces. High-speed electrical signals of the computing modules are transmitted through circuit board traces to an edge of the on-chip all-optical switching network module, where the high-speed electrical signals are loaded onto optical signals by the analog electrical transceiver chips. The optical signals then propagate at high speed within the optical interposer layer and are scheduled and switched by a plurality of on-chip optical switches and optical-switching control analog electrical chips on the photonic chip. Optical paths are reconfigured through on-chip optical switching, thereby enabling reconfigurable optical interconnection among different computing modules, such that high-speed electrical signals of the computing modules can reach other computing modules with minimum latency.

Furthermore, in an exemplary embodiment, a method of manufacturing a semiconductor device comprises:
providing a circuit board having a plurality of electrical connection paths;
providing an on-chip all-optical switching network module, the on-chip all-optical switching network module comprising a photonic chip and a plurality of analog electrical transceiver chips mounted above the photonic chip, the photonic chip comprising a plurality of communication nodes respectively communicatively connected to the plurality of analog electrical transceiver chips, a plurality of optical connection paths, and at least one on-chip optical switch configured to reconfigure a connection topology among the plurality of communication nodes;
providing a plurality of computing modules; and
mounting the on-chip all-optical switching network module and the plurality of computing modules on the circuit board, wherein the plurality of computing modules are respectively communicatively connected to the plurality of analog electrical transceiver chips through the plurality of electrical connection paths on the circuit board, such that a connection topology among the plurality of computing modules is reconfigurable through the at least one on-chip optical switch.

In some embodiments of the present invention, the circuit board has a first socket, and mounting the on-chip all-optical switching network module on the circuit board comprises removably inserting the on-chip all-optical switching network module into the first socket.

In some embodiments of the present invention, the photonic chip comprises at least two photonic integrated circuit sub-chips, adjacent photonic integrated circuit sub-chips are optically interconnected with one another, and each photonic integrated circuit sub-chip is fabricated using a full-reticle photomask exposure process.

It should be understood by those skilled in the art that the above disclosure merely illustrates exemplary embodiments of the present invention and is not intended to limit the scope of the claims. Any equivalent modifications or variations made in accordance with the embodiments of the present invention shall fall within the scope of the appended claims. For example, the technical solutions of the present invention are not limited to semiconductor devices including eight computing modules as illustrated in the drawings, but may also be applied to semiconductor devices including fewer than eight or more than eight computing modules. In addition, the present invention is not limited to communication between computing modules, and may be applied to communication between any communication devices. That is, the computing modules described herein may be replaced with any module, unit, or device having a signal transmission function. It should be understood by those skilled in the art that such variations also fall within the scope of the present application.

1. A semiconductor device, comprising:
a circuit board comprising a plurality of electrical connection paths;
an on-chip all-optical switching network module mounted on the circuit board, the on-chip all-optical switching network module comprising:
a photonic chip; and
a plurality of analog electrical transceiver chips mounted above the photonic chip,
wherein the photonic chip comprises:
a plurality of communication nodes respectively communicatively connected to the plurality of analog electrical transceiver chips,
a plurality of optical connection paths, and
at least one on-chip optical switch configured to reconfigure a connection topology among the plurality of communication nodes; and
a plurality of computing modules mounted on the circuit board, and respectively communicatively connected to the plurality of analog electrical transceiver chips through the plurality of electrical connection paths on the circuit board, such that a connection topology among the plurality of computing modules is reconfigurable through the at least one on-chip optical switch.

2. The semiconductor device according to claim 1, wherein:
the circuit board comprises a first socket; and
the on-chip all-optical switching network module is removably inserted into the first socket.

3. The semiconductor device according to claim 2, wherein:
the circuit board comprises a plurality of mounting regions;
the plurality of computing modules are respectively mounted in the plurality of mounting regions; and
the plurality of computing modules are communicatively connected to the first socket through the plurality of electrical connection paths.

4. The semiconductor device according to claim 3, wherein:
the plurality of computing modules comprise a first computing module and a second computing module; and
a communication path between the first computing module and the second computing module comprises:
a first electrical connection path connecting the first computing module to the first socket;
a second electrical connection path connecting the first socket to a first analog electrical transceiver chip;
a third electrical connection path connecting the first analog electrical transceiver chip to a first communication node;
a first optical connection path coupling the first communication node to the at least one on-chip optical switch;
a second optical connection path coupling the at least one on-chip optical switch to a second communication node;
a fourth electrical connection path connecting the second communication node to a second analog electrical transceiver chip;
a fifth electrical connection path connecting the second analog electrical transceiver chip to the first socket; and
a sixth electrical connection path connecting the first socket to the second computing module.

5. The semiconductor device according to claim 1, wherein:
the photonic chip comprises at least two photonic integrated circuit sub-chips, adjacent photonic integrated circuit sub-chips are optically interconnected with one another;
each photonic integrated circuit sub-chip comprises at least two communication nodes, a plurality of the optical connection paths, and at least one on-chip optical switch; and
communication between any two communication nodes on the photonic chip is achieved through the at least one on-chip optical switch and the plurality of optical connection paths.

6. The semiconductor device according to claim 5, wherein:
the on-chip all-optical switching network module further comprises at least one optical-switching control analog electrical chip; and
the at least one optical-switching control analog electrical chip is mounted above a corresponding one of the at least one on-chip optical switch and is configured to control the corresponding on-chip optical switch.

7. The semiconductor device according to claim 5, wherein each communication node comprises:
an electrical-to-optical conversion unit configured to convert information carried by an electrical signal into an optical signal for transmission; and
an optical-to-electrical conversion unit configured to convert a received optical signal into an electrical signal carrying received information.

8. The semiconductor device according to claim 7, wherein:
the electrical-to-optical conversion unit comprises a modulator or a modulator array; and/or
the optical-to-electrical conversion unit comprises a detector or a detector array.

9. The semiconductor device according to claim 8, wherein:
the modulator comprises a microring modulator, a Mach-Zehnder modulator, or an electro-absorption modulator; and/or
the detector comprises a microring detector or a photodiode.

10. The semiconductor device according to claim 8, wherein each photonic integrated circuit sub-chip further comprises:
an optical input coupler; and
an optical power splitter,
wherein:
the optical input coupler of one of the photonic integrated circuit sub-chips is configured to couple light from an off-chip light source into the photonic chip; and
the optical power splitter is optically connected to the optical input coupler and configured to split the light from the optical input coupler into a plurality of optical outputs,
wherein each optical outputs has substantially the same optical power and is respectively transmitted to a corresponding modulator.

11. The semiconductor device according to claim 10, wherein:
the plurality of optical connection paths comprise first-type optical waveguides; and
adjacent photonic integrated circuit sub-chips are optically interconnected through the first-type optical waveguides.

12. The semiconductor device according to claim 11, wherein:
the first-type optical waveguides of adjacent photonic integrated circuit sub-chips that face each other at a junction therebetween are configured such that a cross-section area of each first-type optical waveguide gradually increases from one photonic integrated circuit sub-chip toward the other photonic integrated circuit sub-chip.

13. The semiconductor device according to claim 10, wherein:
the plurality of optical connection paths further comprise second-type optical waveguides;
in each photonic integrated circuit sub-chip, the second-type optical waveguides are disposed in a different layer from the first-type optical waveguides;
in each photonic integrated circuit sub-chip, one or more of the at least one on-chip optical switch, the electrical-to-optical conversion unit, the optical-to-electrical conversion unit, the optical input coupler, and the optical power splitter are optically connected to corresponding first-type optical waveguides through corresponding second-type optical waveguides; and
the second-type optical waveguides are optically connected to the first-type optical waveguides through evanescent-wave couplers.

14. The semiconductor device according to claim 5, wherein:
the at least one on-chip optical switch comprises a silicon photonic switch including a plurality of optical switching units; and
the at least one optical-switching control analog electrical chip is configured to control the plurality of optical switching units to schedule and switch data transmitted through the silicon photonic switch, such that the connection topology among the plurality of communication nodes is reconfigurable.

15. The semiconductor device according to claim 14, wherein:
each optical switching unit comprises a Mach-Zehnder interferometer structure.

16. The semiconductor device according to claim 5, wherein:
each photonic integrated circuit sub-chip is fabricated using a full-reticle photomask exposure process.

17. The semiconductor device according to claim 1, wherein:
each computing module comprises a digital electrical chip and a memory.

18. A method of manufacturing a semiconductor device according to claim 1, comprising:
providing a circuit board having a plurality of electrical connection paths;
providing an on-chip all-optical switching network module comprising:
a photonic chip; and
a plurality of analog electrical transceiver chips mounted above the photonic chip,
wherein the photonic chip comprises:
a plurality of communication nodes respectively communicatively connected to the plurality of analog electrical transceiver chips,
a plurality of optical connection paths, and
at least one on-chip optical switch configured to reconfigure a connection topology among the plurality of communication nodes;
providing a plurality of computing modules; and
mounting the on-chip all-optical switching network module and the plurality of computing modules on the circuit board,
wherein the plurality of computing modules are respectively communicatively connected to the plurality of analog electrical transceiver chips through the plurality of electrical connection paths on the circuit board, such that a connection topology among the plurality of computing modules is reconfigurable through the at least one on-chip optical switch.

19. The method according to claim 18, wherein:
the circuit board comprises a first socket; and
mounting the on-chip all-optical switching network module on the circuit board comprises removably inserting the on-chip all-optical switching network module into the first socket.

20. The method according to claim 18, wherein:
the photonic chip comprises at least two photonic integrated circuit sub-chips, adjacent photonic integrated circuit sub-chips are optically interconnected with one another; and
each photonic integrated circuit sub-chip is fabricated using a full-reticle photomask exposure process.
